(19) United States
(12) Patent Application Publication
(10) Pub. No.: US 2005/0280035 A1
(43) Pub. Date: Dec. 22, 2005

(54) Semiconductor device and method for fabricating the same

(76) Inventors: Sung-Kwon Lee, Kyoungki-do (KR); Tae-Woo Jung, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/029,783

(22) Filed: Dec. 21, 2004

(30) Foreign Application Priority Data
Jun. 18, 2004 (KR) 2004-45734

(51) Int. Cl. H01L 29/45; H01L 21/82

(52) U.S. Cl. 257/208; 257/211; 438/128; 438/129

(57) ABSTRACT

Disclosed are a semiconductor device and a method for fabricating the same capable of preventing a bridge generation between plugs during forming a plurality of hole type contact plugs for forming storage nodes. The semiconductor device includes: a first gate structure and a second gate structure placed in parallel by a predetermined space; a plurality of bit lines placed on upper portions of the first gate structure and the second gate structure with crossing the first gate structure and the second gate structure; a first cell contact plug and a second cell contact plug located through the plurality of bit lines and formed between the first gate structure and the second gate structure; and an inter-layer insulation layer provided with a first storage node contact hole and a second storage node contact hole connected with each other by etching the inter-layer insulation layer on upper portions of the plurality of bit lines.

### FIELD OF THE INVENTION

The present invention relates to a semiconductor device; and more particularly, to a method for fabricating a plurality of storage node contact plugs in a semiconductor device.

### DESCRIPTION OF RELATED ARTS

In general, a semiconductor device is comprised of a plurality of unit pixels inside of the semiconductor device. A trend in a large-scale of integration has brought a need to form semiconductor devices densely within a confined cell region. Thus, the size of unit devices of a semiconductor device, for instance, transistors and capacitors, has been gradually decreased. Particularly, in a dynamic random access memory (DRAM) device, the size of the unit devices formed within a cell region has been decreased as the design rule has been shifted towards minimization. For instance, DRAM devices are currently formed to have a minimum linewidth less than 0.1 μm and are often required to have a linewidth less than 80 nm. Hence, there exist many difficulties in applying conventional fabrication methods.

In case of applying a photolithography using ArF having a wavelength of 193 nm to a semiconductor device having a linewidth less than 80 nm, it is necessary to develop an additional recipe for preventing a photoresist deformation created during an etching process employed for the purposes of forming a fine pattern and a vertical etch profile.

Meanwhile, advancement in an integration level of a semiconductor device has led device elements to be formed in stacks. A contact plug or a contact pad is one example of such stack structure.

For the contact plug, a landing plug contact (LPC) is commonly used since the LPC has a bottom portion which makes a wide contact within a minimum area and a top portion which is wider than the bottom portion for increasing a contact margin.

Furthermore, for forming such a LPC, there is a difficulty of etching between structures having a high aspect ratio. At this time, a self-aligned contact (SAC) etching process obtaining an etch profile by using an etch selectivity ratio of two materials, e.g., an oxide layer and a nitride layer is introduced.

For the SAC etching process, CF and CHF based gases are used, and it is also necessary to have an etch stop layer using a nitride layer for the purpose of preventing an attack to a conductive pattern of a lower portion or a spacer.

FIG. 1 is a top view illustrating a conventional semiconductor device provided with a plurality of storage node contact holes.

Referring to FIG. 1, a plurality of line shaped gate structures G1 to G6 expanded in a direction of Y are placed by a fixed distance ‘D’ apart. A pitch of the semiconductor device can be obtained by a width ‘W’ of the plurality of gate structures G1 to G6 and the distance ‘D’ of the plurality of gate electrodes G1 to G6 and thus, a typical pitch of the semiconductor device is approximately (W+D)/2. A plurality of inter-layer insulation layers ILD patterned by a mask pattern for forming an I-type cell contact plug are placed on the plurality of gate structures G1 to G6. A plurality of cell contact plugs P contacted with a substrate between the plurality of gate structures G1 to G6 and planarized with upper portions of the plurality of gate structures G1 to G6 are placed. A plurality of bit line contact plugs BLC overlapped with some portions of the plurality of cell contact plugs P are placed between the plurality of gate structures G1 to G6. A plurality of line-type bit lines B/L1 to B/L4 expanded in a direction of X crossing the plurality of gate structures G1 to G6 are connected to the plurality of bit line contact plugs BLC. A plurality of hole type storage node contact holes SNC1 to SNC4 exposing the plurality of cell contact plugs P that will be contacted with the storage nodes are formed to align with the plurality of bit lines B/L1 to B/L4.

Herein, the plurality of cell contact plugs P placed in a lower portion of the plurality of bit line contact plugs BLC are omitted and the plurality of storage node contact holes SNC use a hole type mask.

FIGS. 2A to 2D are cross-sectional views illustrating a conventional process for forming a plurality of storage node contact plugs. With reference to FIGS. 2A to 2D, the conventional process for forming the plurality of storage node contact plugs is examined.

FIGS. 2A to 2D correspond to a cross-sectional view taken along a line A-A′ of FIG. 1.

As shown in FIG. 2A, a first inter-layer insulation layer 201 is formed on a substrate 200 provided with various device elements such as a well and a transistor.

In case of using an oxide layer based material layer to form the first inter-layer insulation layer 201, a layer selected from a group of a boro-silicate-glass (BSG) layer, a tetra-ethyl-ortho-silicate (TEOS) layer, a high density plasma (HDP) oxide layer, a spin-on-glass (SOG) layer and an advanced planarization layer (APL) layer is used and except for the oxide layer based material layer, an organic or inorganic based low k-dielectric layer can be used.

Herein, a gate electrode pattern is not shown.

Subsequently, the first inter-layer insulation layer 201 is selectively etched, thereby forming a plurality of contact holes exposing an impurity diffusion region (not shown) of the substrate 200.

Next, a conductive layer such as a polysilicon layer is deposited to fill the plurality of contact holes and then, a planarization process to expose a plurality of gate hard masks is performed, thereby forming a plurality of isolated cell contact plugs 202.

Subsequently, a second inter-layer insulation layer 203 is formed on the plurality of cell contact plugs 202. The second inter-layer insulation layer 203 is made of one of the oxide-based material layer and the low k-dielectric layer practically used for forming the first inter-layer insulation layer 201.

Subsequently, although not shown, the second inter-layer insulation layer 203 is selectively etched, thereby exposing some portions of the plurality of cell contact plugs 202 and defining regions where a plurality of bit lines B/L will be formed. Afterwards, a plurality of bit line contact plugs (not shown) are formed by using a similar process with the process used for forming the plurality of cell contact plugs 202. Next, the plurality of bit lines B/L electrically connected with the plurality of bit line contact plugs are formed.

The bit line conductive layer 204 is made of a material selected from a group consisting of polysilicon, tungsten (W), tungsten nitride (WNₓ), tungsten silicide (WSiₓ). Also, it is possible to form the bit line conductive layer 204 by using a material combining all of the above listed materials.

The bit line hard mask 205 is made for the purpose of protecting the bit line conductive layer 204 in the course of forming the contact holes by etching an inter-layer insulation layer during an etching process and uses a material having a very different etching speed from that of the inter-layer insulation layer. For instance, in case of using the oxide-based material for the inter-layer insulation layer, a nitride-based material such as a silicon nitride (SiN)⁻ layer or a silicon oxynitride (SiON) layer is used and in case of using a polymer based low k-dielectric layer for forming the inter-layer insulation layer, the oxide-based material is used. The plurality of spacers 206 are made for the purpose of preventing a damage on the plurality of bit lines B/L during the etching process employed by using a subsequent SAC etching process along a profile formed with the plurality of bit lines B/L.

In case of the plurality of spacers 206, a nitride-based insulation layer is deposited along the profile formed with the plurality of bit lines B/L, and thus the plurality of spacers 206 are formed on lateral sides of each of the plurality of bit lines B/L through a blanket etch-back process.

Afterwards, an oxide-based third inter-layer insulation layer 207 is formed on upper portions of the plurality of bit lines B/L. The third inter-layer insulation layer 207 is also formed by using a similar material with that used for forming the first and the second inter-layer insulation layers 201 and 203.

Next, one of a chemical mechanical polishing (CMP) process denoted with a reference numeral 208 for removing a height difference of an upper portion of the third inter-layer insulation layer 207 and an etch back process locally performed is employed, thereby planarizing a surface of the third inter-layer insulation layer 207.

Subsequently, as shown in FIG. 2B, a plurality of mask patterns 209 for forming the storage node contact plugs are formed on the planarized third inter-layer insulation layer 207.

Herein, the plurality of mask patterns 209 may be one of a typical photoresist pattern, a photoresist pattern and a sacrificial hard mask, and a sacrificial hard mask.

The sacrificial hard mask may use W, Polysilicon, or the nitride layer in order to prevent a pattern deformation and secure an etch tolerance of the photoresist due to a limitation of a resolution during the photolithography process.

Meanwhile, during forming the photoresist pattern, an anti-reflective coating layer can be used between the photoresist pattern and lower layers of the photoresist pattern. The anti-reflective coating layer is used between the photoresist pattern and the lower layers of the photoresist pattern for the purpose of preventing an undesirable pattern formation from a scattered reflection due to a high degree of light reflection during a photo-exposure for a pattern formation and improving an adhesiveness between the photoresist pattern and the lower layers of the photoresist pattern.

At this time, the anti-reflective coating layer mainly uses an organic based material having a similar etching property with the photoresist pattern. However, according to a process, the anti-reflective coating layer can be omitted.

More specific to the process for forming the photoresist pattern, a photoresist for ArF or F₂ light source, e.g., COMA or acrylaid which is the photoresist for ArF or F₂ light source, is coated on the lower structure of the anti-reflective coating layer or a material layer for the sacrificial hard mask in a predetermined thickness by performing a spin coating method. Afterwards, predetermined portions of the photoresist are selectively photo-exposed by employing a lithography device using a ArF or F₂ light source and a predecided reticle (not shown) for defining a width of a contact hole. Thereafter, a developing process proceeds by making a photo-exposed portion or a non-photo-exposed portion remain, and a cleaning process is then performed to remove etch remnants, thereby forming the photoresist pattern which is a cell contact open mask. Herein, the photoresist pattern and the mask pattern 209 are hole types.

As shown in FIG. 2C, the SAC etching process etching the second and the third inter-layer insulation layers 203 and 207 by using the plurality of mask patterns 209 as an etch mask is performed, thereby forming a plurality of contact holes 21 aligning with the plurality of bit lines B/L and exposing the plurality of cell contact plugs 202.

At this time, a typical recipe for the SAC etching process is employed. That is, a fluoride based plasma, e.g., CₓF_{y} (x and y range from approximately 1 to approximately 10) gas such as C₂F₄, C₂F₆, C₃F₈, C₄F₆, C₅F₈ or C₅F₁₀, is used as a main gas along with an additional CₐH_{b}F_{c} (a, b and c range from approximately 1 to approximately 10) gas such as CH₂F₂, C₃HF₅ or CHF₃. At this time, an inert gas such as He, Ne Ar or Xe is used as a carrier gas.

Meanwhile, in case of using a material layer for forming the sacrificial hard mask, the material layer for forming the sacrificial hard mask is etched by using the photoresist pattern as the etch mask, thereby forming the sacrificial hard mask defining regions where a plurality of storage node contact plugs will be formed. Afterwards, the SAC etching process etching the second and the third inter-layer insulation layer 203 and 207 is performed by using the sacrificial hard mask as the etch mask.

Subsequently, the photoresist pattern is removed by performing a photoresist stripping process. In case of using an organic based anti-reflective coating layer as the photoresist pattern, the photoresist pattern is also removed by the photoresist stripping process. However, in case of using the sacrificial hard mask as the photoresist pattern, the photoresist pattern can be removed after a contact opening process or during a plug isolation process.

Next, in order to expand a plurality of openings placed in lower portions of the plurality of storage node contact holes 210, an additional etching process using buffered oxide etchant (BOE) is performed. Meanwhile, in case of using a nitride-based etch stop layer on upper portions of the plurality of cell contact plugs 202 to prevent a damage on the plurality of cell contact plugs 202, this etch stop layer is removed during performing this additional etching process.

Next, a cleaning process is performed to remove impurities and an interface oxide layer formed on lower portions of the plurality of storage node contact holes 210 before deposition of a conductive layer for forming the contact plugs. At this time, the BOE is used.

Next, referring to FIG. 2D, the plurality of contact holes 210 are buried by depositing the conductive layer for forming the contact plug. Afterwards, a plurality of isolated storage node contact plugs 211 are formed by performing the planarization process in order to expose the third inter-layer insulation layer 207.

The conductive layer for filling the contact plugs uses a material selected from a group consisting of a TiN layer, a polysilicon layer, a Ti layer and a W layer. Also, the conductive layer for forming the contact plugs can be formed by stacking the above materials. During planarizing the conductive layer for forming the contact plugs, one of the CMP process, the etch back process and both the CMP process and the etch back process is used.

As described in FIG. 1 and FIGS. 2A to 2D, a hole type which is already proved by previous process technology is used as a shape of the mask pattern for forming the storage node contact holes in accordance with the conventional method.

The process forming the hole type storage node contact holes has a relatively high compensation margin to a damage of the hard mask for forming the gate electrode or the bit line compared with the I-type or a line type.

However, in the process applied with the design rule equal to or less than approximately 80 nm, forming the storage node contact holes by using the hole type mask is theoretically considered reaching a limitation. It is not avoidable to reduce a critical dimension CD of the lower portions of the contact holes since the openings of the hole type storage node contact holes are very small.

Due to a lack of the margin of the inter-layer insulation layer created by a decrease of the design rule, the upper portions of the inter-layer insulation layers are damaged after the SAC etching process performed for forming the storage node contact holes, thereby generating a bridge phenomenon denoted with a reference denotation Y between the plurality of storage nodes even after performing a plug isolation process.

### SUMMARY OF THE INVENTION

It is, therefore, an object of the present invention to provide a semiconductor device and a method for fabricating the same capable of preventing a bridge generation between plugs during forming a plurality of hole type storage node contact plugs.

In accordance with one aspect of the present invention, there is provided a semiconductor device, including: a first gate structure and a second gate structure placed in parallel by a predetermined space; a plurality of bit lines placed on upper portions of the first gate structure and the second gate structure with crossing the first gate structure and the second gate structure; a first cell contact plug and a second cell contact plug located through the plurality of bit lines and formed between the first gate structure and the second gate structure; and an inter-layer insulation layer provided with a first storage node contact hole and a second storage node contact hole connected with each other by etching the inter-layer insulation layer on upper portions of the plurality of bit lines.

In accordance with one aspect of the present invention, there is provided a method for fabricating a semiconductor device, including the steps of: forming a plurality of cell contact plugs on a substrate; forming a first insulation layer on the plurality of cell contact plugs; forming a plurality of bit lines on the first insulation layer; forming a second insulation layer on the plurality of bit lines; forming a plurality of mask patterns with a shape to expose the second insulation layer in a plurality of hole type regions to define a storage node contact hole region, wherein the hole type regions adjacent to each other between the bit lines are connected with each other on the upper portions of the plurality of bit lines; and forming a plurality of storage node contact holes by etching the first insulation layer and the second insulation layer with use of the plurality of mask patterns as an etch mask to expose the plurality of cell contact plugs and to make an etch profile align with the plurality of bit lines.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a top view illustrating a conventional semiconductor device provided with a plurality of storage node contact holes;

FIGS. 2A to 2D are cross-sectional views illustrating a conventional process for forming a plurality of storage node contact plugs;

FIG. 3 is a top view provided with a plurality of storage node contact holes in accordance with the present invention;

FIGS. 4A to 4D are cross-sectional views illustrating a process for forming a plurality of storage node contact plugs in accordance with a first embodiment of the present invention; and

FIGS. 5A and 5B are cross-sectional views illustrating a process for forming a plurality of storage node contact plugs in accordance with a second embodiment of the present invention.

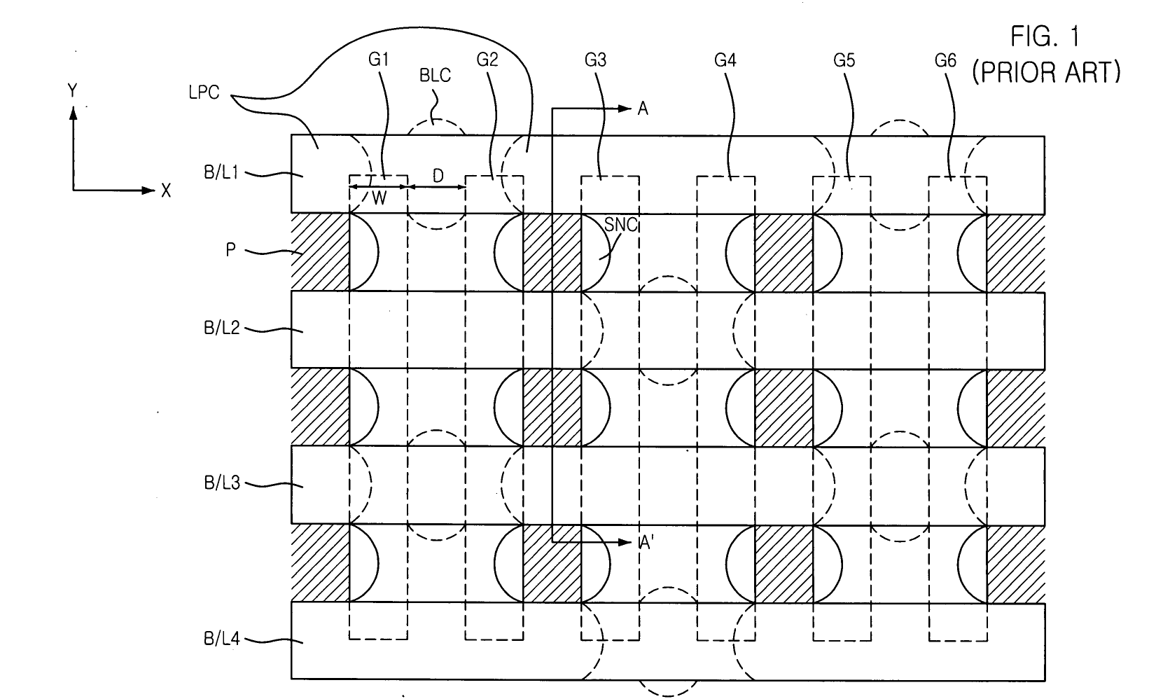

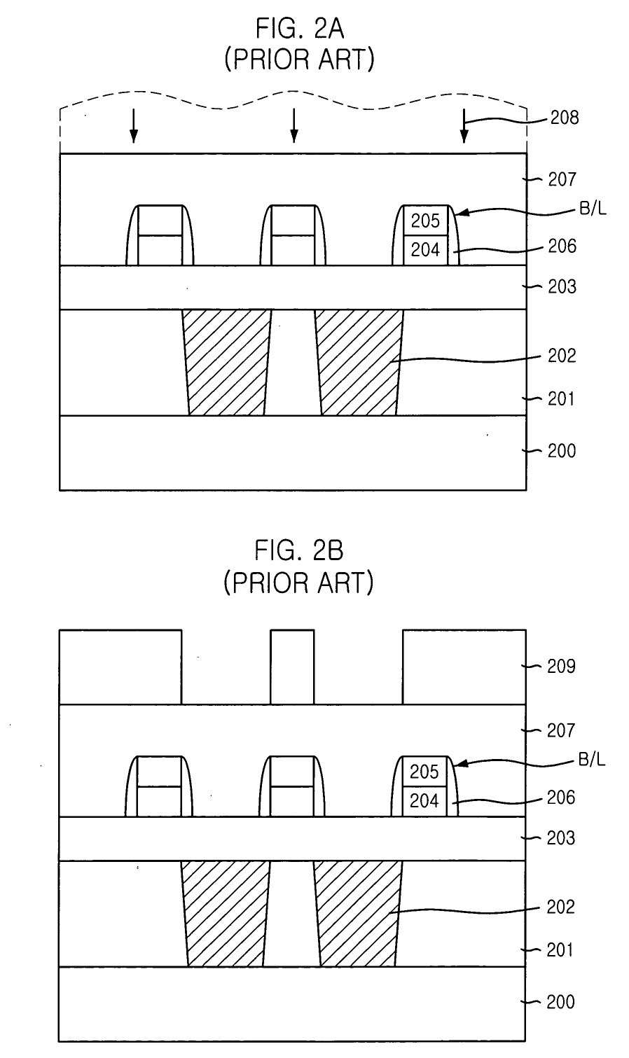

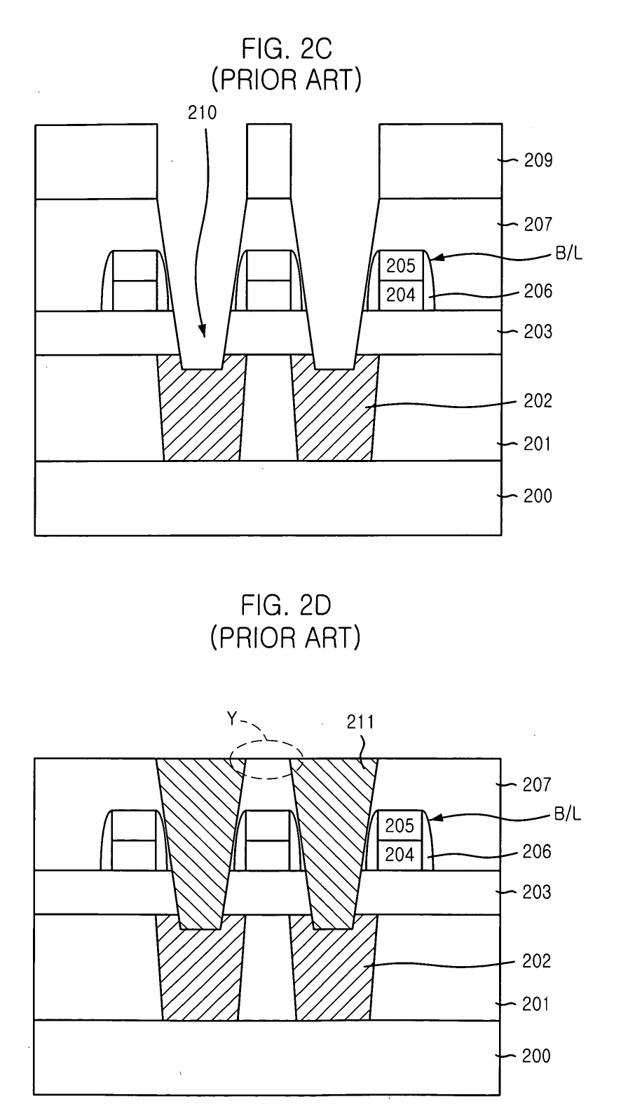

### DETAILED DESCRIPTION OF THE INVENTION

Hereinafter, detailed descriptions on preferred embodiments of the present invention will be provided with reference to the accompanying drawings.

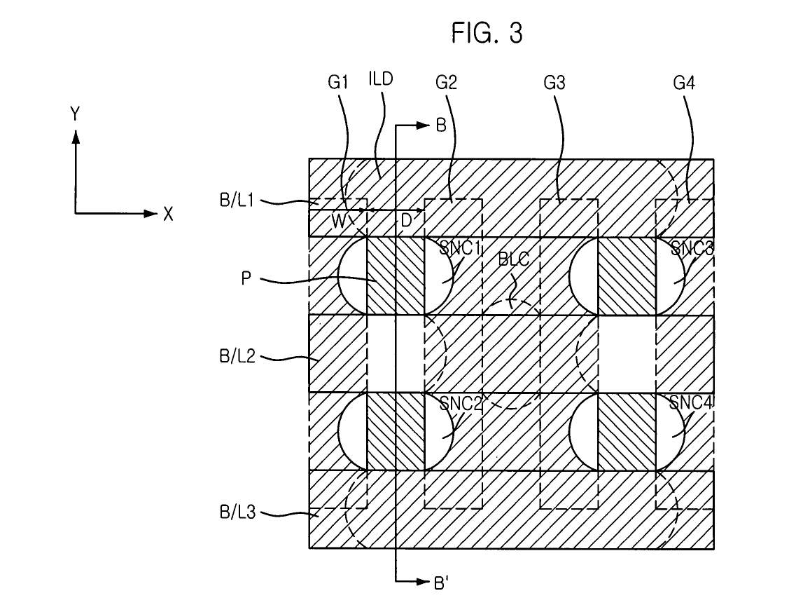

FIG. 3 is a top view illustrating a semiconductor device provided with a plurality of storage node contact holes.

Referring to FIG. 3, a plurality of line shaped gate structures G1 to G4 expanded in a direction of Y are placed by a fixed distance ‘D’ apart. A pitch of the semiconductor device can be obtained by a width ‘W’ of the plurality of gate structures G1 to G4 and the distance ‘D’ of the plurality of gate structures G1 to G4. Herein, the pitch of the semiconductor device is approximately (W+D)/2.

A plurality of line shaped bit lines B/L1 to B/L3 expanded in a direction of X crossing the plurality of gate structures G1 to G4 are placed on upper portions of the plurality of gate structures G1 to G4. An inter-layer insulation layer ILD is placed on the plurality of bit lines B/L1 to B/L3.

A plurality of cell contact plugs P contacted with a substrate between the plurality of gate structures G1 to G4 and planarized with the upper portions of the plurality of gate structures G1 to G4 and the inter-layer insulation layer ILD are placed. A bit line contact BLC overlapped thereby to contact with some portions of the plurality of cell contact plugs P is placed between the plurality of gate structures G1 to G4. The plurality of bit lines B/L1 to B/L3 are contacted with the bit line contact BLC. A plurality of hole type storage node contact holes SNC1 to SNC4 exposing the plurality of cell contact plugs P that will be contacted with the storage nodes are formed to align with the plurality of bit lines B/L1 to B/L3.

The plurality of cell contact plugs P can use either an I-type or a T-type mask pattern. Herein, among the plurality of storage node contact holes SNC1 to SNC4, one pair of the storage node contact holes SNC1 and SNC2 and the other pair of the storage node contact holes SNC3 and SNC4 are respectively connected with each other by etching the inter-layer insulation layer ILD on upper portions of the plurality of bit lines B/L1 to B/L3. For instance, as shown in FIG. 3, among the plurality of storage node contact holes SNC1 to SNC4, the storage node contact holes SNC1 and SNC2, and the storage node contact holes SNC3 and SNC4 are connected with each other by etching the inter-layer insulation layer on the upper portions of the plurality of bit lines B/L1 to B/L3, thereby having dumbbell shapes.

A conductive layer is deposited in the plurality of storage node contact holes SNC1 to SNC4 and as a result, the plurality of storage node contact holes SNC1 to SNC4 are buried. Accordingly, the plurality of storage node contact holes SNC1 to SNC4 are electrically connected with the plurality of cell contact plugs P placed in lower portions and planarized with the upper portions of the plurality of bit lines B/L1 to B/L3, thereby forming a plurality of isolated storage node contact plugs.

At this time, the plurality of storage node contact plugs are made of a material selected form a group consisting of a titanium (Ti) layer, a polysilicon layer, a titanium nitride (TiN) layer and a tungsten (W) layer. Also, the plurality of storage node contact plugs can be formed by using these above materials. The inter-layer insulation layer ILD is made of an oxide-based layer.

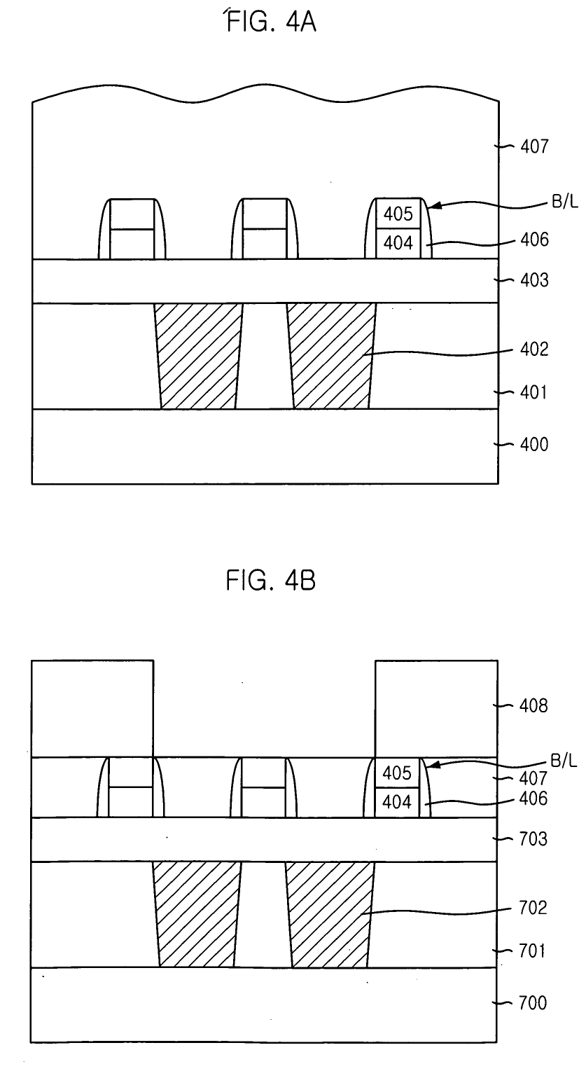

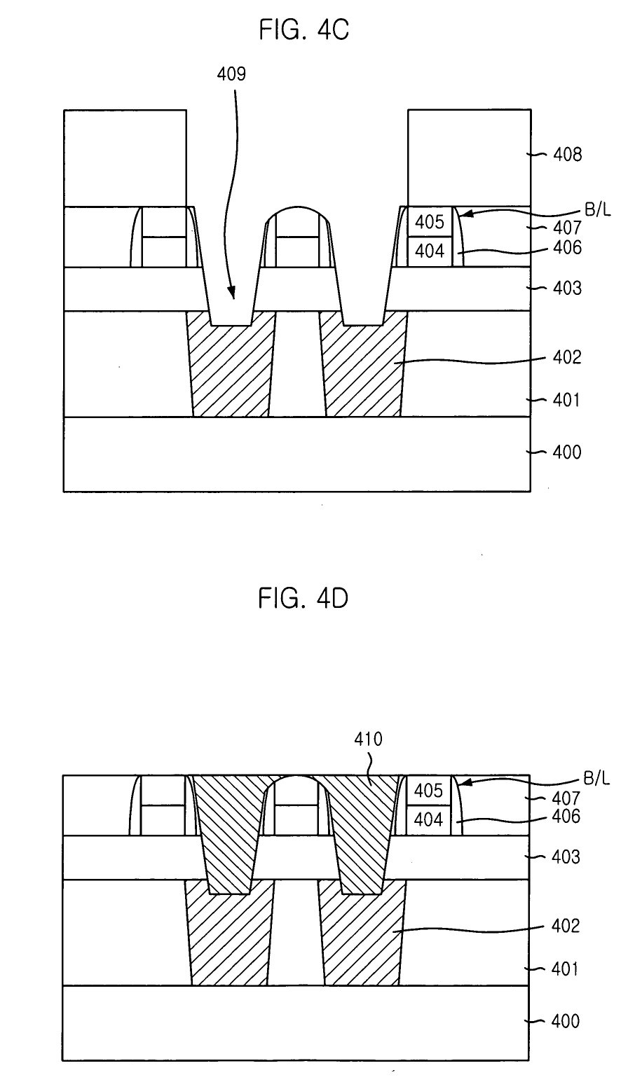

FIGS. 4A to 4D are cross-sectional views illustrating a process for forming a plurality of storage node contact plugs in accordance with a first embodiment of the present invention. With reference to FIGS. 4A to 4D, the process for forming the plurality of storage node contact plugs in accordance with the present invention will be examined.

FIGS. 4A to 4D are cross-sectional views of FIG. 3 taken along a direction of a ling B-B′.

As shown in FIG. 4A, a first inter-layer insulation layer 401 is formed on a substrate 400 provided with various device elements such as a well and a transistor.

In case of using an oxide-based layer to form the first inter-layer insulation layer 401, a layer selected from a group consisting of a boro-silicate-glass (BSG) layer, a boro-phospho-silicate-glass (BPSG) layer, a phosphor-silicate-glass (PSG) layer, a tetra-ethyl-ortho-silicate (TEOS) layer, a high density plasma (HDP) oxide layer, a spin-on-glass (SOG) layer and a flow-fill low temperature oxide layer is used. However, besides using the oxide-based layer, inorganic or organic based low k-dielectric layer can be used for forming the first inter-layer insulation layer 401.

For reference, a gate structure pattern is omitted herein.

Subsequently, the first inter-layer insulation layer 401 is selectively etched, thereby forming a plurality of contact holes exposing an impurity diffusion region (not shown) of the substrate 400. At this time, an self-aligned contact (SAC) etching process is employed.

Next, in order to fill the plurality of contact holes, a conductive layer such as a polysilicon layer is deposited. Afterwards, a planarization process is performed to expose a gate hard mask, thereby forming a plurality of isolated cell contact plugs 402.

Next, a second insulation layer 403 is formed on the plurality of cell contact plugs 402. The second inter-layer insulation layer 403 can be made of either the oxide-based layer or the low k-dielectric layer practically identical with the layer forming the first inter-layer insulation layer 401.

Next, although not shown, the second inter-layer insulation layer 403 is selectively etched, thereby exposing portions of the plurality of cell contact plugs 402. Thus, regions where a plurality of bit lines will be formed are defined and then, a plurality of bit line contact plugs (not shown) are formed by employing a similar process with the process for forming the plurality of cell contact plugs 402. Subsequently, a plurality of bit lines B/L electrically connected with the plurality of bit line contact plugs are formed.

Each of the plurality of bit lines B/L has a structure formed by stacking a bit line hard mask 405 and a bit line conductive layer 404 and includes a plurality of spacers 406 on lateral sides of the above structure. The bit line conductive layer can be made of a material selected from a group consisting of polysilicon, W, tungsten nitride (WN) and tungsten silicide (WSiₓ). Also, the bit line conductive layer can be formed by using all of the above materials.

The bit line hard mask 405 serves a role in protecting the bit line conductive layer 404 in the course of forming the plurality of contact holes by etching the inter-layer insulation layer during the etching process for forming the plurality of storage node contact holes and can be made of a material having a very different etching speed from that of the inter-layer insulation layer. For instance, in case of using an oxide-based layer for forming the inter-layer insulation layer, a nitride-based layer such as silicon nitride (SiN) or silicon oxynitride (SiON) is used, and in case of using a polymer-based low k-dielectric layer for forming the inter-layer insulation layer, an oxide-based layer is used. The pluratliy of spacers 406 play a role in preventing a damage created along a profile provided with the plurality of bit lines B/L during an etching process using a subsequent SAC etching process.

As for the plurality of spacers 406, an insulation layer made of a nitride-based layer is first deposited along the profile provided with the pluratliy of bit lines B/L and then, the pluratliy of spacers 406 are formed on lateral sides of the pluratliy of bit lines B/L through a blanket etch-back process.

Next, a third inter-layer insulation layer 407 made of an oxide-based layer is formed on an upper portion of the above structure provided with the pluratliy of bit lines B/L. The third inter-layer insulation layer 407 also can be formed by using a similar material used for forming the first and the second inter-layer insulation layers 401 and 403.

Next, as shown in FIG. 4B, a planarization process for removing and planarizing a height difference of an upper portion of the third inter-layer insulation layer 407 is performed and then, during the planrization process, the pluratliy of bit line hard masks 405 are exposed to reduce a target that will be etched during the process for forming the plurality of storage node contact holes.

During planarizing the third inter-layer insulation layer 407, a chemical mechanical polishing (CMP) process or a local etch back process is employed.

Subsequently, a mask pattern 408 for forming the plurality of contact plugs is formed on the planarized third inter-layer insulation layer 407 and the plurality of bit line hard masks 405.

Herein, the mask pattern 408 may be a typical photoresist pattern, a photoresist pattern and a sacrificial hard mask or a sacrificial hard mask.

The sacrificial hard mask can be made of a material selected form a group consisting of W, polysilicon, a nitride layer and amorphous carbon to prevent a pattern deformation and to secure an etch tolerance of the photoresist due to a limitation of a resolution during a photolithography process.

Meanwhile, during forming the photoresist pattern, an anti-reflective coating layer can be used between the photoresist pattern and a layer beneath the photoresist pattern. The anti-reflective coating layer is used for the purpose of improving adhesiveness between the photoresist pattern and the layer beneath the photoresist pattern.

At this time, the anti-reflective coating layer mainly uses an organic based material having a similar property with the photoresist pattern. However, according to the process, the anti-reflective coating layer can be omitted.

More specific to the process for forming the photoresist pattern, a photoresist for ArF, KrF or F₂ light source, e.g., COMA or acrylaid which is the photoresist for ArF, KrF or F₂ light source, is coated on the lower structure of the anti-reflective coating layer or a material layer for the sacrificial hard mask in a predetermined thickness by performing a spin coating method. Afterwards, predetermined portions of the photoresist are selectively photo-exposed by employing a lithography device using KrF, ArF or F₂ light source and a predecided reticle (not shown) for defining a width of a contact hole. Thereafter, a developing process proceeds by making a photo-exposed portion or a non-photo-exposed portion remain, and an after-cleaning process is then performed to remove etch remnants, thereby forming the photoresist pattern which is a cell contact open mask.

Herein, the photoresist pattern and the mask pattern 408 expose the third inter-layer insulation layer 408 overlapped with the plurality of cell contact plugs 402 in a hole type and a pluratliy of exposed hole type regions closely located from each other are connected on the upper portions of the plurality of bit lines B/L, thereby forming a dumbbell shape.

Subsequently, referring to FIG. 4C, the SAC etching process etching the second and third inter-layer insulation layers 403 and 407 are performed by using the mask pattern 408 as the etch mask. Hence, the second and the third inter-layer insulation layers 403 and 407 are aligned with the plurality of bit lines B/L, thereby forming a plurality of contact holes 409 exposing the plurality of cell contact plugs 402.

At this time, a typical recipe for the SAC etching process is employed. That is, a fluoride based plasma, e.g., CₓF_{y} (x and y range from approximately 1 to approximately 10) gas such as C₂F₄, C₂F₆, C₃F₈, C₄F₆, C₅F₈ or C₅F₁₀ , is used as a main gas along with an additional CₐH_{b}F_{c} (a, b and c range from approximately 1 to approximately 10) gas such as CH₂F₂, C₃HF₅ or CHF₃. At this time, an inert gas such as He, Ne Ar or Xe is used as a carrier gas.

Meanwhile, in case of using a material layer for forming the sacrificial hard mask, the material layer for the sacrificial hard mask is first etched by using the photoresist pattern as the etch mask, thereby forming the sacrificial hard mask defining regions where the plurality of storage node contact plugs will be formed. Afterwards, the SAC etching process etching the second and the third inter-layer insulation layers 403 and 407 are performed by using the sacrificial hard mask as the etch mask.

Next, the photoresist pattern is removed by employing a photoresist stripping process. In case of using an organic based anti-reflective coating layer, the photoresist pattern is removed by applying the photoresist stripping process. However, in case of using the sacrificial hard mask, the photoresist pattern is removed either after a contact opening process or during a plug isolation process.

Next, in order to expand a plurality of openings of lower portions of the plurality of storage node contact holes 409, an additional process using BOE is performed. Meanwhile, in case of using the nitride-based etch stop layer on upper portions of the plurality of cell contact plugs 402 to prevent a damage on the plurality of cell contact plugs 402, the etch stop layer can be removed through an additional etching process.

Next, a cleaning process is performed before a deposition of the conductive layer for forming the plurality of contact plugs to remove an interface oxide layer formed in lower portions of the plurality of storage node contact holes 409 and impurities. At this time, BOE is used.

Next, as shown in FIG. 4D, the plurality of storage node contact holes 409 are filled by depositing the conductive layer for forming the contact plugs. Afterwards, a plug planarization process is performed to expose the third inter-layer insulation layer 407, thereby forming a plurality of isolated storage node contact plugs 410.

The conductive layer for forming the contact plugs is made of a material selected from a group consisting of a TiN layer, a polysilicon layer, a Ti layer and a W layer. Also, the conductive layer for forming the contact plug uses a structure formed by using all of the above materials. During planarizing, a CMP process, an etch back process or a both the CMP and the etch back processes are used.

In accordance with the first embodiment, the third inter-layer insulation layer 407 are removed up to a portion where the plurality of bit line hard masks 405 are existed, thereby reducing an etch target. And, the mask patterns 408 for forming the plurality of contact holes are formed in a structure that the plurality of storage node contact holes are closely located through the bit line, thereby having a dumbbell shape. Thus, it is possible to prevent a damage on the plurality of storage node contact plugs, which is caused by a loss of the third inter-layer insulation layer 407 between upper portions of the plurality of bit lines.

Meanwhile, in accordance with the first embodiment described above, the third inter-layer insulation layer 407 are removed up to the portion where the plurality of bit line hard masks are existed, thereby performing the process for reducing the etch target. However, another embodiment which does not employ the process described above will be explained.

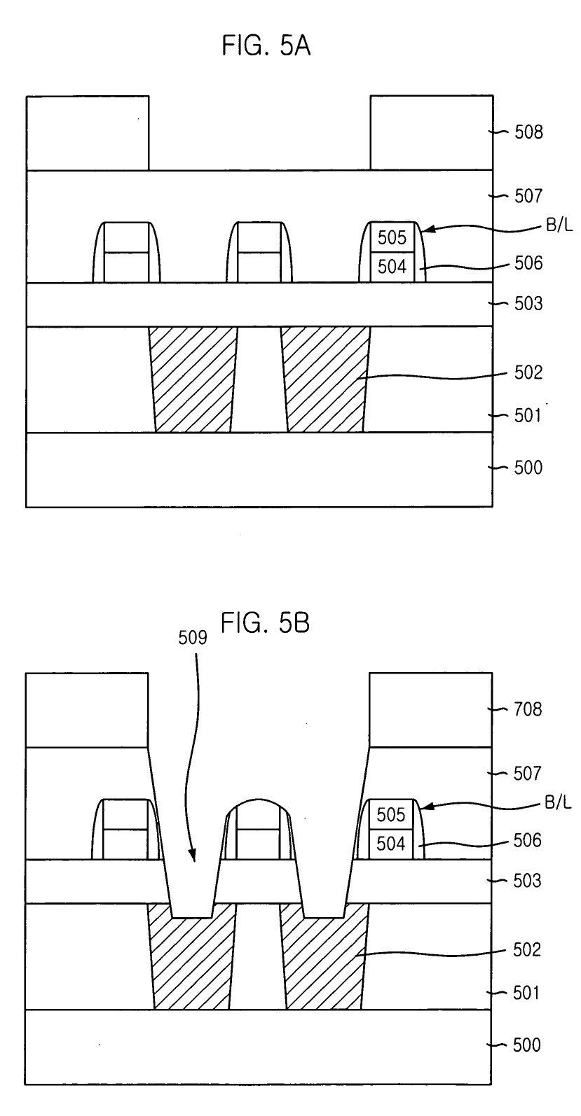

FIGS. 5A to 5B are cross-sectional views illustrating a process for forming a plurality of storage node contact plugs in a semiconductor device in accordance with a second embodiment of the present invention.

Herein, detailed explanations about identical constitution elements with the first embodiment are omitted.

That is, although not shown, a third insulation layer 507 is deposited as shown in FIG. 4A. Afterwards, referring to FIG. 5A, a height difference of the third inter-layer insulation layer is removed and a typical planarization process raising a degree of uniformity of a surface of the third inter-layer insulation layer 507 is performed. Then, a mask pattern 508 is formed.

Referring to FIG. 5B, a second and a third inter-layer insulation layers 503 and 507 are etched by using the mask pattern 508 as an etch mask, thereby forming a plurality of storage node contact plugs 509 exposing a plurality of cell contact plugs 502.

At this time, the third inter-layer insulation layer 507 is almost removed on an upper portion of the bit lines B/L placed between the plurality of storage node contact holes 509.

Next, subsequent processes performed in FIG. 4D are employed.

As described in the first embodiment, even though the third inter-layer insulation layer is not planarized by the plurality of bit line hard masks, the mask pattern for forming the plurality of contact holes is formed in a structure that the plurality of storage node contact holes are closely located through the bit line, thereby forming a dumbbell shape. Thus, it is possible to prevent a damage on the plurality of storage node contact plugs due to a damage of the third inter-layer insulation layer 407 between upper portions of the plurality of bit lines B/L.

The present invention provides an effect of improving yields of semiconductor devices by controlling a bridge generation between a plurality of contact plugs during forming a plurality of hole type storage node contact plugs.

The present application contains subject matter related to the Korean patent application No. KR 2004-0045734, filed in the Korean Patent Office on Jun. 18, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. A semiconductor device, comprising:
a first gate structure and a second gate structure placed in parallel by a predetermined space;
a plurality of bit lines placed on upper portions of the first gate structure and the second gate structure with crossing the first gate structure and the second gate structure;
a first cell contact plug and a second cell contact plug located through the plurality of bit lines and formed between the first gate structure and the second gate structure; and
an inter-layer insulation layer provided with a first storage node contact hole and a second storage node contact hole connected with each other by etching the inter-layer insulation layer on upper portions of the plurality of bit lines.

2. The semiconductor device of claim 1, wherein the inter-layer insulation layer is formed by etching the inter-layer insulation layer in a hole type to be aligned with the plurality of bit lines and exposing each of the first cell contact plug and the second cell contact plug.

3. The semiconductor device of claim 1, wherein the first storage node contact hole and the second storage node contact hole are connected each other in a shape of dumbbell.

4. The semiconductor device of claim 1, wherein further including a first storage node contact plug and a second storage node contact plug isolated from each other by planarizing the plurality of bit lines and the inter-layer insulation layer and electrically connected to each of the first cell contact plug and the second cell contact plug by filling the first storage node contact hole and the second storage node contact hole.

5. The semiconductor device of claim 1, wherein the inter-layer insulation layer is an oxide-based layer.

6. The semiconductor device of claim 2, wherein further including a first storage node contact plug and a second storage node contact plug isolated from each other by planarizing the plurality of bit lines and the inter-layer insulation layer and electrically connected to each of the first cell contact plug and the second cell contact plug by filling the first storage node contact hole and the second storage node contact hole.

7. The semiconductor device of claim 2, wherein the inter-layer insulation layer is an oxide-based layer.

8. The semiconductor device of claim 3, wherein the first storage node contact plug and the second storage node contact plug are made of a material selected from a group consisting of titanium (Ti), polysilicon, titanium nitride (TiN) and tungsten (W) and a combination thereof.

9. The semiconductor device of claim 4, wherein the first storage node contact plug and the second storage node contact plug are made of a material selected from a group consisting of titanium (Ti), polysilicon, titanium nitride (TiN) and tungsten (W) and a combination thereof.

10. A method for fabricating a semiconductor device, comprising the steps of:
forming a plurality of cell contact plugs on a substrate;
forming a first insulation layer on the plurality of cell contact plugs;
forming a plurality of bit lines on the first insulation layer;
forming a second insulation layer on the plurality of bit lines;
forming a plurality of mask patterns with a shape to expose the second insulation layer in a plurality of hole type regions to define a storage node contact hole region, wherein the hole type regions adjacent to each other between the bit lines are connected with each other on the upper portions of the plurality of bit lines; and
forming a plurality of storage node contact holes by etching the first insulation layer and the second insulation layer with use of the plurality of mask patterns as an etch mask to expose the plurality of cell contact plugs and to make an etch profile align with the plurality of bit lines.

11. The method of claim 10, wherein the plurality of mask patterns are connected each other in a shape of dumbbell.

12. The method of claim 10, wherein further including a planarization process removing the second insulation layer to expose upper portions of the plurality of bit lines after the step of forming the second insulation layer.

13. The method of claim 10, wherein the plurality of mask patterns includes one structure selected from a stack of a photoresist pattern, a stack of a photoresist pattern and an organic based anti-reflective coating layer, a stack of a photoresist pattern and a sacrificial hard mask, and a stack of a photoresist pattern, a sacrificial hard mask and an organic based anti-reflective coating layer.

14. The method of claim 10, wherein the first and the second insulation layers include an oxide layer.

15. The method of claim 11, wherein further including a planarization process removing the second insulation layer to expose upper portions of the plurality of bit lines after the step of forming the second insulation layer.

16. The method of claim 11, wherein the plurality of mask patterns includes one structure selected from a stack of a photoresist pattern, a stack of a photoresist pattern and an organic based anti-reflective coating layer, a stack of a photoresist pattern and a sacrificial hard mask, and a stack of a photoresist pattern, a sacrificial hard mask and an organic based anti-reflective coating layer.

17. The method of claim 14, wherein the sacrificial hard mask includes a material selected from a group consisting of polysilicon, tungsten, a nitride layer and amorphous carbon and a combination thereof.

18. The method of claim 15, wherein the sacrificial hard mask includes a material selected from a group consisting of polysilicon, tungsten, a nitride layer and amorphous carbon and a combination thereof.

19. The method of claim 16, wherein in the step of forming the plurality of photoresist patterns, a photolithography using one of ArF, KrF and F₂ light source is employed.

20. The method of claim 17, wherein in the step of forming the plurality of photoresist patterns, a photolithography using one of ArF, KrF and F₂ light source is employed.
